(19) United States
(12) Patent Application Publication
(10) Pub. No.: US 2025/0275392 A1
(43) Pub. Date: Aug. 28, 2025

(54) DISPLAY APPARATUS

(71) Applicant: LG Display Co., Ltd., Seoul (KR)

(72) Inventors: Se-Yeon JUNG, Paju-si (KR); Jeong-Oh KIM, Paju-si (KR); Myung-Jae YOO, Paju-si (KR); Geum-Young LEE, Paju-si (KR); Jae-Choul YU, Paju-si (KR)

(21) Appl. No.: 18/918,914

(22) Filed: Oct. 17, 2024

(30) Foreign Application Priority Data
Feb. 27, 2024 (KR) 10-2024-0027924

(51) Int. Cl. H10K 59/131; H10K 59/124; H10K 59/80

(52) U.S. Cl. CPC H10K 59/131; H10K 59/124; H10K 59/873

(57) ABSTRACT

A display apparatus includes a substrate including a display area including a plurality of sub-pixels and a non-display area outside the display area. The display apparatus includes a thin film transistor and a light emitting diode disposed in each sub-pixel of the display area. The display apparatus includes an encapsulation layer sealing the light emitting diode. The display apparatus includes a plurality of water sensing parts disposed in the non-display area and detecting moisture penetrating. An amount of current in the water sensing part changes according to a change in an amount of moisture penetrating.

### CROSS-REFERENCE TO RELATED APPLICATION

The present application claims priority to Korean Patent Application No. 10-2024-0027924 filed on Feb. 27, 2024, the entire contents of which are hereby expressly incorporated by reference into the present application.

### BACKGROUND

### Technical Field

The present disclosure relates to a display apparatus, and more particularly, to a display apparatus capable of easily detecting permeation of moisture.

### Description of the Related Art

With the development of information technologies, various types of small and thin display devices such as a liquid crystal display device, an organic light emitting display device, a plasma display device, a micro LED display device have been proposed. In addition, these display devices have been applied to various electronic devices such as smartphones, tablet PCs, and so on.

A display device not only has various electrodes formed therein, but also includes various layers and various elements such as a display unit for displaying an image, and so on.

### BRIEF SUMMARY

The inventors of the present disclosure have recognized that in prior art display devices, a problem exists where electrodes become corroded, or the organic light emitting layer deteriorates when moisture or hydrogen from the outside permeates the display device. Accordingly, the present disclosure is directed to a display device that substantially obviates one or more of the technical problems associated with the prior art, including the limitations and disadvantages identified above.

More specifically, the present disclosure provides various embodiments of a display device capable of accurately measuring the location and amount of moisture permeation.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

To achieve these and other aspects of the present disclosure, as embodied and broadly described herein, a display apparatus includes a substrate including a display area including a plurality of sub-pixels and a non-display area outside the display area; a thin film transistor and a light emitting diode disposed in each sub-pixel of the display area; an encapsulation layer sealing the light emitting diode; and a plurality of water sensing parts disposed in the non-display area and detecting moisture penetrating, wherein an amount of current in the water sensing part changes according to a change in an amount of moisture penetrating.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a schematic block diagram of a display apparatus according to the present disclosure;

FIG. 2 is a schematic block diagram of a subpixel shown in FIG. 1;

FIG. 3 is a circuit diagram conceptually showing a sub-pixel of a display apparatus according to the present disclosure;

FIG. 4 is a plan view schematically showing a structure of a display apparatus according to the present disclosure;

FIG. 5 is a block diagram showing a water sensing unit according to the present disclosure;

FIG. 6 is a cross-sectional view showing a structure of a display apparatus according to a first embodiment of the present disclosure;

FIG. 7 is an enlarged cross-sectional view of area A of FIG. 6;

FIG. 8 is a graph showing the relationship between voltage and current detected in a water sensing part; and

FIG. 9 is a cross-sectional view showing a display apparatus according to a second embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, dimensions (e.g., length, width, height, thickness, radius, diameter, area, etc.), ratios, angles, numbers, and the like disclosed in the drawings for describing the embodiments of the present disclosure are illustrative, and thus the present disclosure is not limited to the illustrated matters.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “consisting of,” and the like mentioned in this disclosure are used, other parts can be added unless the term “only” is used herein. When a component is expressed as being singular, being plural is included unless otherwise specified.

In analyzing a component, an error range is interpreted as being included even if there is no explicit description.

In describing a positional relationship, for example, when a positional relationship of two parts is described as being “on,” “above,” “below,” “next to,” or the like, unless “immediately” or “directly” is not used, one or more other parts can be located between the two parts.

In describing a temporal relationship, for example, when a temporal predecessor relationship is described as being “after,” “subsequent,” “next to,” “prior to,” or the like, unless “immediately” or “directly” is not used, cases that are not continuous can also be included.

Although the terms such as first, second, and the like are used to describe various components, these components are not substantially limited by these terms. These terms are used only to distinguish one component from another component. Therefore, a first component described below can substantially be a second component within the technical spirit of the present disclosure.

In describing components of the present disclosure, terms such as first, second, A, B, (a), (b) and the like can be used. These terms are only for distinguishing the components from other components, and an essence, order, order, or number of the components is not limited by the terms. Further, when it is described that a component is “connected,” “coupled” or “contact” to another component, the component can be directly connected or contact the another component, but it should be understood that other component can be “interposed” between the components or the components can be “connected,” “coupled,” or “contact” through one or more other components.

As used herein, the term “apparatus” or “device” can include a narrowly defined display apparatus such as a display module including a display panel and a driving unit for driving the display panel. Further, the term “apparatus” can further include a notebook computer, a television, a computer monitor, an equipment display including an automotive display or other type of vehicle, etc., and a set electronic device or a set device or set apparatus such as a mobile electronic device of a smartphone or an electronic pad, etc., which are a finished product (complete product or final product) including the display module.

Accordingly, the apparatus or device in the present disclosure can include the display apparatus itself such as the display module and the application product including the display module or the set apparatus, which is the apparatus for end users.

Hereinafter, embodiments of the present disclosure will be described with reference to the accompanying drawings.

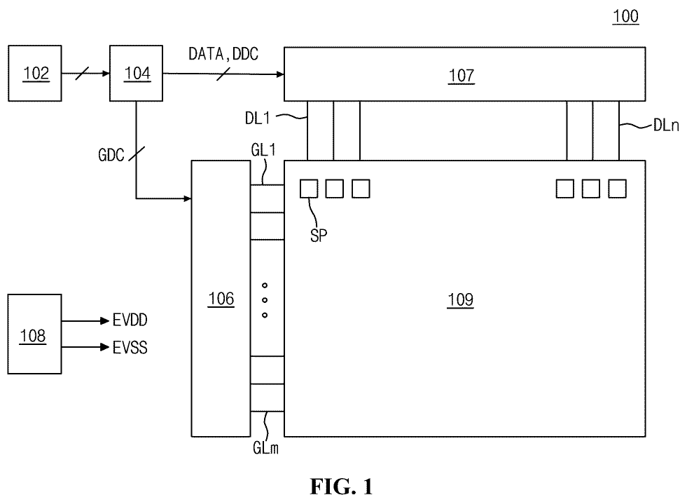

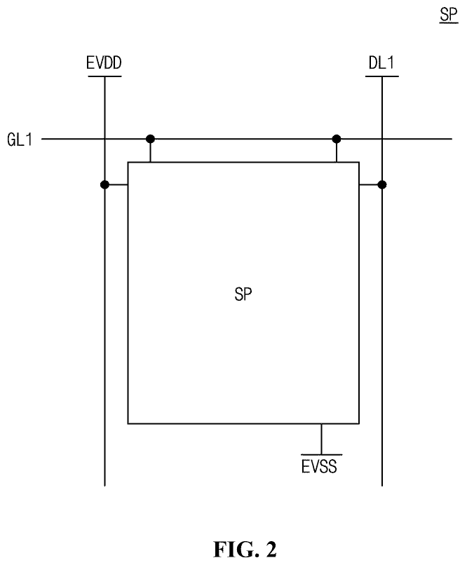

FIG. 1 is a schematic block diagram of a display apparatus according to the present disclosure, and FIG. 2 is a schematic block diagram of a subpixel SP shown in FIG. 1.

In FIG. 1, the display apparatus 100 may include an image processing unit 102, a timing control unit 104, a gate driving unit 106, a data driving unit 107, a power supply unit 108, and a display panel 109.

The term “unit” or “module” as used herein may include any electrical circuitry, features, components, an assembly of electronic components, or the like. That is, “unit” or “module” may include any processor-based system including systems using microcontrollers, integrated circuits, chips, microchips, reduced instruction set computers (RISC), application specific integrated circuits (ASICs), field-programmable gate arrays (FPGAs), graphical processing units (GPUs), logic circuits, and any other circuit or processor capable of executing the various operations and functions described herein. The above examples are examples only, and are thus not intended to limit in any way the definition or meaning of the term “unit” or “module.”

In some embodiments, the various units or modules described herein may be included in or otherwise implemented by processing circuitry such as a microprocessor, microcontroller, or the like.

The image processing unit 102 may output image data supplied from the outside as well as driving signals for driving various devices. For example, the driving signals output from the image processing unit 102 may include a data enable signal, a vertical synchronization signal, a horizontal synchronization signal, and a clock signal.

The timing control unit 104 may receive the image data and the driving signals from the image processing unit 102. The timing control unit 104 may generate and output a gate timing control signal GDC for controlling the operation timing of the gate driving unit 106 and a data timing control signal DDC for controlling the operation timing of the data driving unit 107 based on the driving signals input from the image processing unit 102.

The gate driving unit 106 may output scan signals to the display panel 109 in response to the gate timing control signal GDC supplied from the timing control unit 104. The gate driving unit 106 may output the scan signals through a plurality of gate lines GL1 to GLm. Here, the gate driving unit 106 may be formed in the form of an integrated circuit (IC), but is not limited thereto. The gate driving unit 106 may include various gate driving circuits, and the gate driving circuits may be formed directly on a substrate of the display panel 109. In this case, the gate driving unit 106 may be referred to a GIP (gate-in-panel).

The data driving unit 107 may output data voltages to the display panel 109 in response to the data timing control signal DDC supplied from the timing control unit 104. The data driving unit 107 may sample and latch a digital data signal supplied from the timing control unit 104 and convert it into an analog data voltage based on a gamma voltage. The data driving unit 107 may output the data voltages through a plurality of data lines DL1 to DLn. At this time, the data driving unit 107 may be formed in the form of an integrated circuit (IC), but is not limited thereto.

The power supply unit 108 may output a high potential voltage VDD and a low potential voltage VSS and supply the high potential voltage VDD and the low potential voltage VSS to the display panel 109. The high potential voltage VDD may be supplied to the display panel 109 through a first power line EVDD, and the low potential voltage VSS may be supplied to the display panel through a second power line EVSS. At this time, a voltage output from the power supply unit 108 may be output to the gate driving unit 106 or the data driving unit 107 and used to drive the gate driving unit 106 or the data driving unit 107.

The display panel 109 may display an image in response to the data voltage supplied from the data driving unit 107, the scan signal supplied from the gate driving unit 106, and the voltage supplied from the power supply unit 108.

The display panel 109 may include a plurality of sub-pixels SP and actually display an image. The sub-pixels SP may include a red sub-pixel, a green sub-pixel, and a blue sub-pixel or a white sub-pixel, a red sub-pixel, a green sub-pixel, and a blue sub-pixel. At this time, the white, red, green, and blue sub-pixels may have the same area or may have different areas.

As shown in FIG. 2, one sub-pixel SP may be connected to a gate line GL1, a data line DL1, a first power line EVDD, and a second power line EVSS. The sub-pixel SP may include a plurality of thin film transistors and at least one storage capacitor depending on the configuration of the pixel circuit. For example, the sub-pixel SP may include two transistors and one capacitor (2T1C). However, embodiments of the present disclosure are not limited thereto. In other embodiments, the sub-pixel SP may be implemented to include 3T1C, 4T1C, 5T1C, 6T1C, 7T1C, 3T2C, 4T2C, 5T2C, 6T2C, 7T2C, or 8T2C.

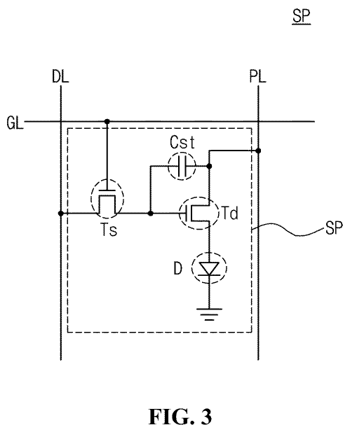

FIG. 3 is a circuit diagram conceptually showing a sub-pixel of a display apparatus according to the present disclosure.

As shown in FIG. 3, the display apparatus of the present disclosure may include a gate line GL, a data line DL, and a power line PL that cross each other to define a sub-pixel SP. A switching transistor Ts, a driving transistor Td, a storage capacitor Cst, and a light emitting diode D may be disposed in the sub-pixel SP.

The switching transistor Ts may be connected to the gate line GL and the data line DL, the driving transistor Td and the storage capacitor Cst may be connected between the switching transistor Ts and the power line PL, and the light emitting diode D may be connected to the driving transistor Td.

In the display apparatus with this structure, when the switching transistor Ts is turned on according to the gate signal applied to the gate line GL, the data signal applied to the data line DL may be applied to a gate electrode of the driving transistor Td and an electrode of the storage capacitor Cst through the switching transistor Ts.

The driving transistor Td may be turned on according to the data signal applied to the gate electrode thereof, and as a result, a current proportional to the data signal may flow from the power line PL to the light emitting diode D through the driving transistor Td, and the light emitting diode D may emit light with a luminance proportional to the current flowing through the driving transistor Td.

At this time, the storage capacitor Cst may be charged with a voltage proportional to the data signal, so that the voltage of the gate electrode of the driving transistor Td can be maintained constant during one frame.

In the figure, only two transistors Td and Ts and one capacitor Cst are provided. However, embodiments of the present disclosure are not limited thereto, and three or more transistors and two or more capacitors may be provided.

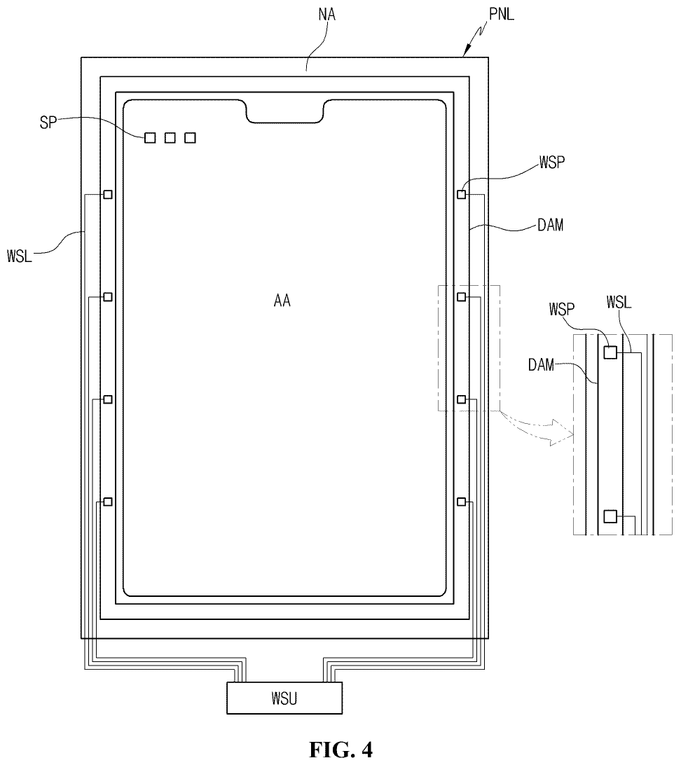

FIG. 4 is a plan view schematically showing a structure of a display apparatus according to the present disclosure.

In FIG. 4, the display apparatus 100 according to the present disclosure may include a display panel PNL displaying an image and a sensing circuit WSU (or also referred to as ‘a water sensing unit WSU’) disposed outside the display panel PNL. The display panel PNL may include a display area AA where the image is actually displayed and a non-display area NA placed outside the display area AA.

A plurality of sub-pixels SP may be disposed in the display area AA. The sub-pixels SP may include a red sub-pixel, a green sub-pixel, and a blue sub-pixel. In addition, the sub-pixels SP may further include a white sub-pixel.

Although not shown in the figure, the plurality of gate lines and the plurality of data lines may be disposed in the display area AA, and the sub-pixel SP may be disposed at each crossing point of the gate lines and the data lines. In each sub-pixel SP, the thin film transistor that is a switching element and a display element for implementing an image may be disposed.

The display element may include various elements. For example, the display element may be an organic electroluminescent display element, a liquid crystal display element, a quantum dot display element, a micro LED display element, or a mini LED display element.

A gate driving unit and a data driving unit for applying various signals to the sub-pixels SP may be disposed in the non-display area NA. The gate driving unit may apply the scan signal to the sub-pixel SP through the gate line, and the data driving unit may apply the image signal to the sub-pixel SP through the data line.

A dam DAM surrounding the display area AA may also be formed in the non-display area NA. When the thin film transistor or the organic light emitting layer of the display apparatus 100 is exposed to external impurities such as air or moisture, the thin film transistor or the organic light emitting layer may deteriorate, and a defect may occur in the display apparatus 100. Accordingly, an encapsulation layer (not shown) may be formed in the display apparatus 100 to seal the display apparatus 100 from the external environment. As will be explained later, the dam DAM may be formed in the non-display area NA to block the flow of the encapsulating material when applying the encapsulating material to form the encapsulation layer, thereby preventing the encapsulating material from flowing to the outside of the display apparatus 100.

In the figure, although one dam DAM is shown as being disposed in the non-display area NA, a plurality of dams DAM surrounding the outside of the display area AA may be disposed in the non-display area NA. The reason for forming the plurality of dams DAM is as follows.

If the encapsulation layer is not formed to a uniform thickness throughout the display apparatus 100, poor image quality may occur due to light refraction at the interface of the encapsulation layer. The reason why the encapsulation layer is not formed to a uniform thickness is because the spreading speed is non-uniform when the encapsulating material is dropped and spread throughout the display apparatus 100. That is, when the encapsulating material spreads in all directions of the display apparatus 100, the spreading speeds are different depending on the directions. Thus, a larger amount of the encapsulating material than the predetermined amount may be applied to certain areas, and a smaller amount of the encapsulating material than the predetermined amount may be applied to other areas, so that the cured encapsulation layer may be formed with a non-uniform thickness.

The poor image quality may occur especially when the encapsulation layer is formed to a thickness equal to or smaller than the predetermined thickness. Accordingly, in order to form the entire encapsulation layer to a thickness greater than the predetermined thickness in a general display apparatus, a larger amount of the encapsulating material than the predetermined amount may be dropped considering the difference in the spreading speeds, and by forming the plurality of dams DAM, the encapsulating material exceeding the predetermined amount can be thoroughly prevented from spreading outside.

In addition, a sensing part WSP (or also referred to as ‘a water sensing part WSP’) may be disposed in the non-display area NA to detect moisture and/or hydrogen penetrating from the outside. Since the moisture and/or hydrogen can permeate through the entire area of the display apparatus 100, the water sensing part WSP may be disposed at a regular interval along the entire perimeter of the display area AA. Further, although not shown in the figure, the water sensing part WSP may be disposed in specific areas. The water sensing part WSP may be disposed only in areas where stress is periodically applied and cracks are likely to occur, for example, to a folding area of a foldable display apparatus or a curved area of a flexible display apparatus.

In the figure, a plurality of water sensing parts WSP may be disposed along the entire perimeter of the display area AA with a predetermined interval therebetween, but embodiments of the present disclosure are not limited thereto. For example, in areas where cracks occur, by decreasing an interval between the water sensing parts WSP, a relatively large number of water sensing parts WSP may be disposed, and in areas where cracks do not occur, by increasing an interval between the water sensing parts WSP, a relatively small number of water sensing parts WSP may be disposed.

As shown in the figure, the water sensing part WSP may be disposed to overlap the dam DAM. However, embodiments of the present disclosure are not limited thereto, and in other embodiments, the water sensing part WSP may be disposed in a different area from the dam DAM.

In the non-display area NA, a plurality of sensing lines WSL (or also referred to as ‘a plurality of water sensing lines WSL’) may be disposed. The plurality of water sensing lines WSL may be connected to respective water sensing parts WSP, each thereby applying a voltage to the water sensing part WSP and simultaneously measuring and detecting a current.

The water sensing lines WSL may be connected to the water sensing unit WSU. The water sensing unit WSU may detect the current input through the water sensing line WSL from the water sensing part WSP to thereby determine whether moisture or hydrogen has permeated.

In the figure, although the water sensing unit WSU is shown as being disposed outside the display panel PNL, embodiments of the present disclosure are not limited thereto. In other embodiments, the water sensing unit WSU may be disposed in a lower portion of the non-display area NA of the display panel PNL. In addition, the water sensing unit WSU may be connected to an external system outside the display apparatus 100 to thereby determine whether moisture has permeated during the manufacturing process of the display apparatus 100.

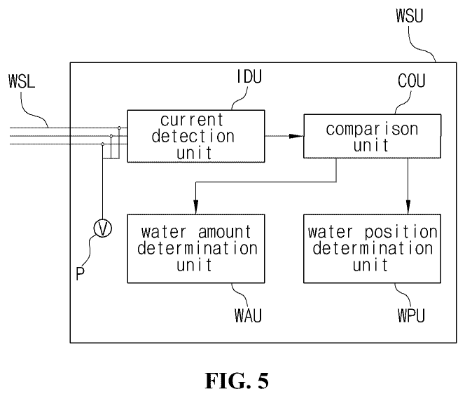

FIG. 5 is a block diagram showing the water sensing unit WSU according to the present disclosure.

As shown in FIG. 5, the water sensing unit WSU may include a current detection unit IDU, a comparison unit COU, a water position determination unit WPU, and a water permeation amount determination unit or water amount determination unit WAU. The current detection unit IDU may detect the current input from the water sensing part WSP. The comparison unit COU may compare the current detected by the current detection unit IDU with the reference value. The water position determination unit WPU, which is a water permeation position determination unit, may determine the area where moisture is detected, that is, the area where moisture permeates, according to the value compared by the comparison unit COU. The water amount determination unit WAU, which is a water permeation amount determination unit, may determine the amount of moisture that has permeated according to the value compared by the comparison unit COU.

The reference value stored in the comparison unit COU may store the allowable amount of moisture to permeate. That is, when the moisture permeates into the display apparatus 100, the reference value at which the display apparatus 100 becomes defective may be stored. The water position determination unit WPU may determine the moisture permeation position by detecting a current that exceeds the reference value stored in the comparison unit COU among a plurality of currents input from the plurality of water sensing parts WSP.

When each measured current value is smaller than the predetermined reference value, the water amount determination unit WAU may determine that it is not moisture permeation affecting the display apparatus 100, and may not determine the location or amount of moisture permeation. The water amount determination unit WAU may determine the location or amount of measured moisture permeation only when the measured current value is greater than the predetermined reference value.

However, embodiments of the present disclosure are not limited thereto. In other embodiments, the water amount determination unit WAU may detect the location and amount of moisture permeation whenever any moisture permeation is detected regardless of the amount of moisture permeation, and may determine the risk of moisture permeation using a separate method.

The amount of moisture permeation can be determined based on a table of current versus moisture permeation amount set in the water amount determination unit WAU. However, embodiments of the present disclosure are not limited thereto.

In addition, the water sensing unit WSU may include a voltage source P and may apply a voltage or voltages to the plurality of water sensing lines WSL.

As described above, in the present disclosure, by providing the water sensing part WSP, it is possible to quickly and easily check whether moisture or hydrogen permeates, so that defects in the display apparatus 100 due to permeation of moisture or hydrogen can be easily detected.

Particularly, in the present disclosure, the location of moisture penetrating can be accurately detected, so that actions to the location of moisture permeation can be quickly and accurately taken. Further, since the amount of moisture penetrating can be accurately detected, only the display apparatus 100 in which moisture permeates to a degree that actually affects the display apparatus 100 may be judged as defective, and the display apparatus 100 in which a small amount of moisture permeates may be judged as normal, so that the number of display apparatus 100 being discarded due to defects can be reduced or minimized.

Hereinafter, the specific structure of the display apparatus 100 according to an embodiment of the present disclosure will be described with reference to accompanying drawings.

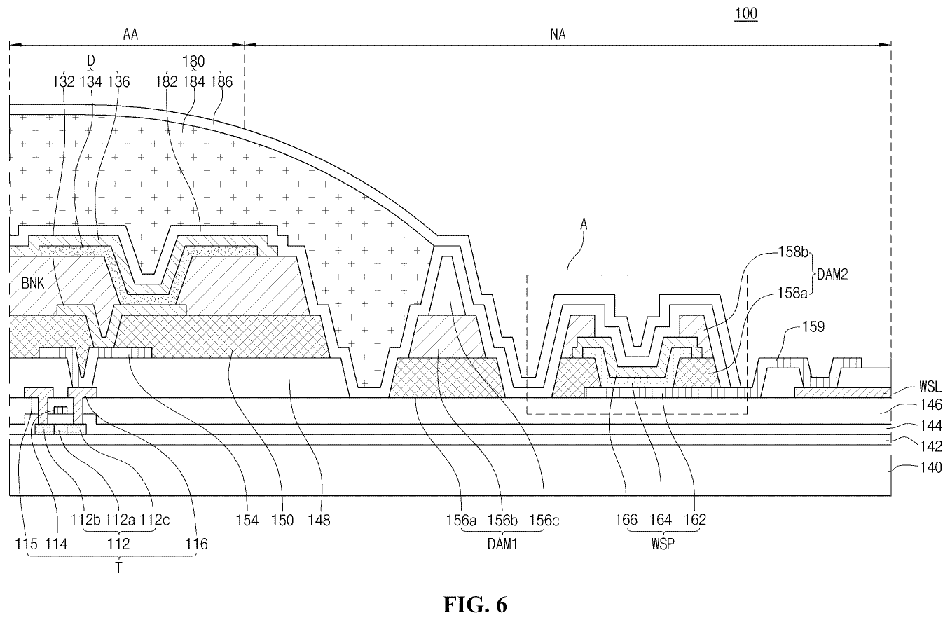

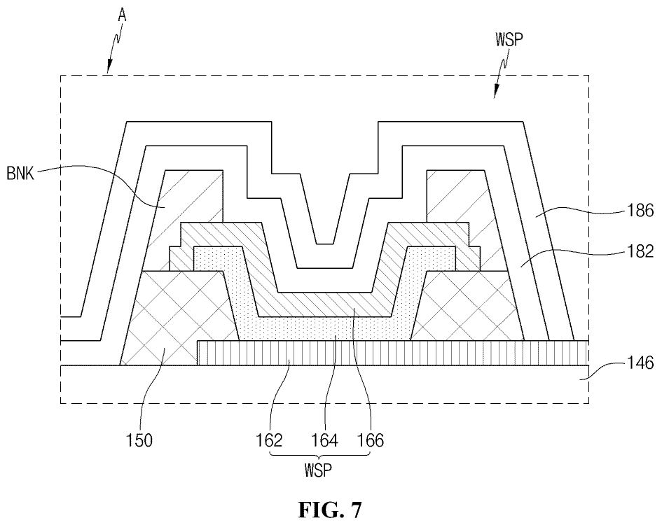

FIG. 6 is a cross-sectional view showing a structure of a display apparatus 100 according to a first embodiment of the present disclosure, and FIG. 7 is an enlarged cross-sectional view of area A of FIG. 6. At this time, a display area AA and a non-display area NA are shown in the figures for convenience of explanation. Actually, a plurality of thin film transistors and various lines are disposed in the display area AA and the non-display area NA, but for convenience of explanation, only the thin film transistor disposed in the display area AA is shown in the figure.

As shown in FIG. 6 and FIG. 7, a substrate 140 may include the display area AA and the non-display area NA. The substrate 140 may be formed of a hard material such as glass or a plastic-based material having flexibility.

When the substrate 140 is formed of a plastic-based material, the substrate 140 may be formed of at least one of polyimide, polymethylmethacrylate, polyethylene terephthalate, polyethersulfone, and polycarbonate, but embodiments of the present disclosure are not limited thereto.

For example, when the substrate 140 is formed of polyimide, the substrate 140 may include a plurality of polyimide layers, and an inorganic layer may be further disposed between the polyimide layers. However, embodiments of the present disclosure are not limited thereto.

A buffer layer 142 may be formed on the substrate 140. The buffer layer 142 may be formed over a substantially entire surface of the substrate 140 to improve the adhesion between the substrate 140 and the layers formed on the substrate 140 and to block alkaline components leaking from the substrate 140. In addition, the buffer layer 142 may delay the diffusion of moisture or oxygen that permeates into the substrate 140.

The buffer layer 142 may be formed as a single layer of SiNx or SiOx or multiple layers thereof. When the buffer layer 142 is formed as multiple layers, SiOx and SiNx may be formed alternately. The buffer layer 142 may be omitted based on the type and material of the substrate 140, the structure and type of the thin film transistor, and so on.

The thin film transistor T may be formed on the buffer layer 142 in the display area AA and may be a driving thin film transistor. For convenience of explanation, only the driving thin film transistor among various thin film transistors that can be disposed in the display area AA may be shown in the figure, but other thin film transistors such as switching thin film transistors may also be included. In addition, the thin film transistor may be shown as having a top gate structure in the figure, but embodiments of the present disclosure are not limited thereto. In other embodiments, the thin film transistor may have other structures such as a bottom gate structure.

The thin film transistor T may include a semiconductor layer 112, a gate insulation layer 144, a gate electrode 114, an interlayer insulation layer 146, a source electrode 115, and a drain electrode 116. The semiconductor layer 112 may be disposed on the buffer layer 142, the gate insulation layer 144 may be formed on the semiconductor layer 112, the gate electrode 114 may be disposed on the gate insulation layer 144, the interlayer insulation layer 146 may be formed on the gate electrode 114, and the source electrode 115 and the drain electrode 116 may be disposed on the interlayer insulation layer 146.

The semiconductor layer 112 may be formed of polycrystalline semiconductor. For example, the polycrystalline semiconductor maybe low temperature polycrystalline silicon (LTPS) with relatively high mobility, but embodiments of the present disclosure are not limited thereto.

Alternatively, the semiconductor layer 112 may be formed of oxide semiconductor. For example, the semiconductor layer 112 may be formed of one of IGZO (indium gallium zinc oxide), IZO (indium zinc oxide), IGTO (indium gallium tin oxide), and IGO (indium gallium oxide), but embodiments of the present disclosure are not limited thereto. The semiconductor layer 112 may include a channel region 112a in the central region and a source region 112b and a drain region 112c as doping layers on both sides of the channel region 112a.

The gate insulation layer 144 may be formed in both the display area AA and the non-display area NA or may be formed only in the display area AA. The gate insulation layer 144 may be formed as a single layer of an inorganic material such as SiNx or SiOx or multiple layers thereof. However, embodiments of the present disclosure are not limited thereto.

The gate electrode 114 may be disposed on the gate insulation layer 144 to overlap the channel region 112a.

The interlayer insulation layer 146 may be formed in both the display area AA and the non-display area NA or may be formed only in the display area AA. The interlayer insulation layer 146 may be formed of an organic material such as photosensitive acrylic polymer (photo acryl) or may be formed as a single layer of an inorganic material such as SiNx or SiOx or multiple layers thereof. In addition, the interlayer insulation layer 146 may be formed as multiple layers of an organic material layer and an inorganic material layer, but embodiments of the present disclosure are not limited thereto.

The source electrode 115 and the drain electrode 116 on the interlayer insulation layer 146 may be formed as a single layer or multiple layers of one of molybdenum (Mo), aluminum (Al), chromium (Cr), gold (Au), titanium (Ti), nickel (Ni), and neodymium (Nd) or an alloy thereof, but embodiments of the present disclosure are not limited thereto. The source electrode 115 and the drain electrode 116 may be in contact with the source region 112b and the drain region 112c through contact holes formed in the gate insulation layer 144 and the interlayer insulation layer 146, respectively.

Although not shown in the figure, a bottom shield metal may be disposed on the substrate 140 under the semiconductor layer 112. The bottom shield metal may be provided to prevent afterimages or deterioration of the transistor by reducing or minimizing the back channel phenomenon caused by charges trapped in the substrate 140. The bottom shield metal may be formed of titanium (Ti), molybdenum (Mo), or an alloy thereof. The bottom shield metal may be formed as a single layer or multiple layers, but embodiments of the present disclosure are not limited thereto.

A first planarization layer 148 may be formed over the substrate 140 on which the thin film transistor T is provided. The first planarization layer 148 may be formed of an organic material such as photosensitive acrylic polymer (photo acryl), but embodiments of the present disclosure are not limited thereto. In other embodiments, the first planarization layer 148 may be configured as multiple layers including an inorganic layer and an organic layer.

A connection electrode 154 may be disposed on the first planarization layer 148 and may be electrically connected to the drain electrode 116 of the thin film transistor T through a contact hole formed in the first planarization layer 148.

A second planarization layer 150 may be formed on the first planarization layer 148 on which the connection electrode 154 is provided. The second planarization layer 150 may be formed of an organic material such as photosensitive acrylic polymer (photo acryl), but embodiments of the present disclosure are not limited thereto. In other embodiments, the second planarization layer 150 may be configured as multiple layers including an inorganic layer and an organic layer. In addition, the second planarization layer 150 may be formed of the same material as the first planarization layer 148, or may be formed of a different material from the first planarization layer 148.

As such, in the present disclosure, by forming the planarization layer into two-layer structure 148 and 150, various electrodes and lines can be formed between the first and second planarization layers 148 and 150. Accordingly, since the electrodes can be arranged vertically, it is possible to reduce the area due to the electrodes and lines in the sub-pixel, and as a result, the area of the sub-pixel can be reduced, thereby fabricating the high-resolution display apparatus 100.

A light emitting diode D may be disposed on the second planarization layer 150 in the display area AA. The light emitting diode D may include a first electrode 132, a light emitting layer 134, and a second electrode 136.

The first electrode 132 may be disposed on the second planarization layer 150 and may be electrically connected to the connection electrode 154 through a contact hole formed in the second planarization layer 150. The first electrode 132 may be electrically connected to the drain electrode 116 of the thin film transistor T through the connection electrode 154. The first electrode 132 may be formed of one or more of silver (Ag), aluminum (Al), gold (Au), molybdenum (Mo), tungsten (W), chromium (Cr), and an alloy thereof. Alternatively, the first electrode 132 may be formed of a transparent metal oxide material such as ITO (indium tin oxide) or IZO (indium zinc oxide).

When the display apparatus 100 is a top-emission type display apparatus, the first electrode 132 may further include an opaque conductive material to function as a reflection electrode that reflects light. When the display apparatus 100 is a bottom-emission type display apparatus, the first electrode 132 may be formed of a transparent conductive material that transmits light, such as indium tin oxide (ITO) or indium zinc oxide (IZO).

A bank layer BNK may be formed at the boundary of each sub-pixel on the second planarization layer 150. The bank layer BNK may be a type of partition wall that defines a sub-pixel. The bank layer BNK may partition each sub-pixel to prevent light of a specific color from adjacent pixels from being mixed and output.

The bank layer BNK may be formed of one or more of an inorganic insulating material such as SiNx or SiOx, an organic insulating material such as BCB (benzocyclobutene), acryl resin, epoxy resin, phenolic resin, polyamide resin, or polyimide resin, or a photosensitive agent including black pigment, but embodiments of the present disclosure are not limited thereto.

The light emitting layer 134 may be formed on a top surface of the first electrode 132 and an inclined side surface of the bank layer BNK and a part of a top surface of the bank layer BNK in the display area AA and may extend into the non-display area NA.

The light emitting layer 134 may be formed in R, G, and B sub-pixels and may include an R-light emitting layer that emits red light, a G-light emitting layer that emits green light, and a B-light emitting layer that emits blue light. For example, the light emitting layer 134 may include an organic light emitting layer, an inorganic light emitting layer, a nano-sized material layer, a quantum dot light emitting layer, a micro LED light emitting layer, and a mini LED light emitting layer, but embodiments of the present disclosure are not limited thereto.

In addition to the light emitting layer 134, an electron injection layer, a hole injection layer, an electron transporting layer, a hole transporting layer, a hole blocking layer, and an electron blocking layer may be further provided. The electron injection layer may inject electrons to the light emitting layer 134, the hole injection layer may inject holes to the light emitting layer 134, the electron transporting layer may transport electrons to the light emitting layer 134, and the hole transporting layer may transport holes to the light emitting layer 134. However, embodiments of the present disclosure are not limited thereto.

The second electrode 136 may be disposed on the light emitting layer 134 and may be formed as a single layer or multiple layers of metals or alloys thereof. Alternatively, the second electrode 136 may be formed of transparent metal oxide such as indium tin oxide (ITO) or indium zinc oxide (IZO), but embodiments of the present disclosure are not limited thereto.

When the display apparatus 100 is a top-emission type display apparatus, the second electrode 136 may be formed of an opaque conductive material that reflects light. For example, the second electrode 136 may be formed of one or more of LiF/Al, CsF/Al, Mg:Ag, Ca/Ag, Ca:Ag, LiF/Mg:Ag, LiF/Ca/Ag, and LiF/Ca:Ag.

When the display apparatus 100 is a bottom-emission type display apparatus, the second electrode 136 may be formed of a translucent conductive material that transmits light. For example, the second electrode 136 may be formed of one or more of silver (Ag), aluminum (Al), gold (Au), molybdenum (Mo), tungsten (W), chromium (Cr), and an alloy thereof.

In addition, the light emitting diode D may be configured to have a tandem structure. The tandem structure may include a plurality of light emitting layers, and a charge generation layer may be included in the light emitting layers. The charge generation layer may be used to control charge balance between a plurality of organic layers and may include a plurality of layers including a first charge generation layer and a second charge generation layer. The charge generation layer may include an N-type charge generation layer and a P-type charge generation layer. The charge generation layer may be formed of a light emitting layer doped with an alkali metal such as Li, Na, K, or Cs and/or an alkaline earth metal such as Mg, Sr, Ba, or Ra, but embodiments of the present disclosure are not limited thereto.

An encapsulation layer 180 may be formed in the display area AA and the non-display area NA to seal the light emitting diode D. When the light emitting diode D is exposed to moisture or oxygen, a pixel shrinkage phenomenon in which an emission area is reduced or defects where dark spots appear in the emission area may occur. In addition, moisture or oxygen may oxidize electrodes formed of metal. However, in the present disclosure, the encapsulation layer 180 may block permeation of moisture and oxygen and prevent defects in the light emitting diode D and various electrodes.

The encapsulation layer 180 may include a first encapsulation layer 182, a second encapsulation layer 184, and a third encapsulation layer 186, but embodiments of the present disclosure are not limited thereto. In other embodiments, the encapsulation layer 180 may include two layers or have four layers or more.

The first encapsulation layer 182 and the third encapsulation layer 186 may each be formed as a single layer of an inorganic material such as SiOx, SiON, or SiNx or multiple layers including the same and further including an organic material between inorganic materials of SiOx, SiON, or SiNx. However, embodiments of the present disclosure are not limited thereto. In addition, the second encapsulation layer 184 may be formed of epoxy resin.

Although not shown in the figure, a touch member may be provided. The touch member may be provided in the display area AA to detect a touch input. The touch member may detect eternal touch information using the user's finger or a touch pen.

In the non-display area NA, a dam may be provided. For example, in the non-display area NA, a first dam DAM1 and a second dam DAM2 outside the first dam DAM1 may be formed with a predetermined distance therebetween. Since an organic material for forming the second encapsulation layer 184 has fluidity, when the second encapsulation layer 184 is formed, the organic material may pass through the perimeter of the non-display area NA and flow out of the substrate 140 due to the fluidity. The first and second dams DAM1 and DAM2 may be formed to surround the display area AA and trap the organic material flowing out of the substrate 140 when the second encapsulation layer 184 is formed, so that the organic material can be prevented from flowing out of the substrate 140.

In the embodiment, the reason of providing the plurality of dams DAM1 and DAM2 is as follows.

If an encapsulation layer is not formed to a uniform thickness throughout the display apparatus 100, poor image quality may occur due to light refraction at the interface of the encapsulation layer. The reason why the encapsulation layer is not formed to a uniform thickness is because the spreading speed is non-uniform when the encapsulating material is dropped and spread throughout the display apparatus 100. That is, when the encapsulating material spreads in all directions of the display apparatus 100, the spreading speeds are different depending on the directions. Thus, a much smaller amount of the encapsulating material than the predetermined amount may be applied to certain areas, and even areas where the encapsulation material is not applied may exist. The areas where the encapsulation layer is formed to a thickness less than the predetermined thickness is formed or the areas where the encapsulation layer is not formed may be an important cause of defects in the display apparatus because defects such as stains occur due to refraction of transmitted light in the areas.

Accordingly, in order to form the entire encapsulation layer to a thickness greater than the predetermined thickness in a general display apparatus, a larger amount of the encapsulating material than the predetermined amount may be dropped considering the difference in the spreading speeds, and by forming the plurality of dams DAM, the encapsulating material exceeding the predetermined amount can be thoroughly prevented from spreading outside.

The first dam DAM1 may include a first layer 156a, a second layer 156b, and a third layer 156c. In this case, the first layer 156a may be disposed on the interlayer insulation layer 146, and may be formed of the same material as the second planarization layer 150. The second layer 156b may be disposed on the first layer 156a, and may be formed of the same material as the bank layer BNK. The third layer 156c may be disposed on the second layer 156b and may be formed of an organic material. The third 156c may be a spacer on which a metal mask for depositing a light emitting material is placed and supported when the light emitting layer 134 is formed. However, embodiments of the present disclosure are not limited thereto.

The second dam DAM2 may include a fourth layer 158a and a fifth layer 158b. The fourth layer 158a may be disposed on the interlayer insulation layer 146, and may be formed of the same material as the second planarization layer 150. The fifth layer 158b may be disposed on the fourth layer 158a, and may be formed of the same material as the bank layer BNK. However, embodiments of the present disclosure are not limited thereto.

A water sensing part WSP may be disposed in the second dam DAM2. The water sensing part WSP may include a first electrode layer 162, a second electrode layer 166, and an intermediate layer 164 between the first electrode layer 162 and the second electrode layer 166. The conductivity of the intermediate layer 164 may be changed according to the hydrogen concentration.

The first electrode layer 162 may be formed of the same material and through the same process as the connection electrode 154, but embodiments of the present disclosure are not limited thereto.

The intermediate layer 164 may be formed of metal oxide such as IGZO (indium gallium zinc oxide), IZO (indium zinc oxide), IGTO (indium gallium tin oxide), or IGO (indium gallium oxide).

In this case, the intermediate layer 164 may be formed on the first layer 158a of the second dam DAM2 and may be electrically connected to the first electrode layer 162 through a contact hole formed in the first layer 158a.

The second electrode layer 166 may be formed of the same material and through the same process as the first electrode 132 of the light emitting diode D, but embodiments of the present disclosure are not limited thereto.

A water sensing line WSL may be disposed on the interlayer insulation layer 146 in the non-display area NA and may be connected to the external water sensing unit WSU. The water sensing line WSL may be electrically connected to the first electrode layer 162 through a connection line 159.

The water sensing line WSL may be formed of the same material and through the same process as the source electrode 115 of the thin film transistor T, but embodiments are not limited thereto. Alternatively, in other embodiments, the water sensing line WSL may be formed of the same material and through the same process as the first electrode layer 162. In addition, the connection line 159 may be formed may be formed of the same material and through the same process as the first electrode layer 162 or may be formed of the same material and through the same process as the source electrode 115 of the thin film transistor T.

An external voltage may be applied to the first electrode layer 162 of the water sensing part WSP through the water sensing line WSL and the connection line 159, and a reference voltage, for example, a ground voltage may be applied to the second electrode layer 166. A current may be generated between the first electrode layer 162 and the second electrode layer 166 due to the voltage difference between the first electrode layer 162 and the second electrode layer 166, and the current may be input to the water sensing unit WSU through the connection line 159 and the water sensing line WSL.

The conductivity of the intermediate layer 164 between the first electrode layer 162 and the second electrode layer 166 may be changed depending on the permeation of moisture. The current between the first electrode layer 162 and the second electrode layer 166 may vary according to the change of the conductivity, and the water sensing unit WSU may detect the moisture permeation based on the amount of change in the current.

For example, in case that the intermediate layer 164 is formed of metal oxide such as IGZO, when moisture permeates and reaches the intermediate layer 164, hydrogen atom radicals of the moisture penetrate the surface of the intermediate layer 164 and form a metal-OH composite layer. That is, the hydrogen atom radicals react with oxygen ions (O²⁻) bonded to the metal of the metal oxide in the intermediate layer 164 and form hydroxide ions (OH⁻) and electrons (e⁻). Accordingly, electrical conductivity increases due to an increase in electron density in the metal-OH composite layer formed at the surface of the intermediate layer 164.

The increase in electrical conductivity causes an increase in the current generated in the water sensing part WSP, and the water sensing unit WSU can detect the increase in the current to thereby detect the moisture permeation area and the moisture permeation amount.

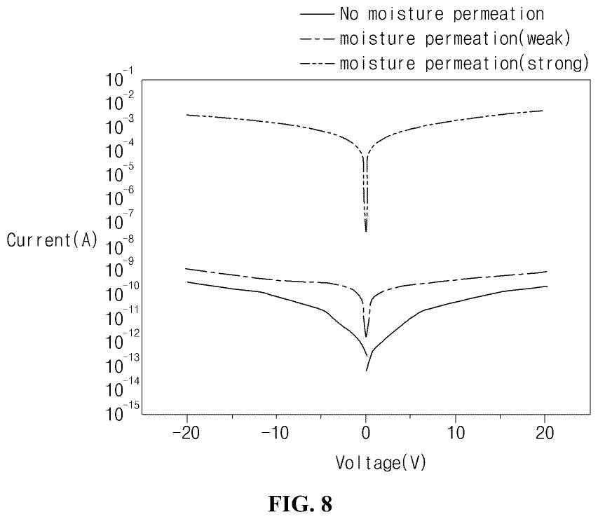

FIG. 8 is a view showing the current detected in the water sensing part WSP and is a graph showing the relationship between voltage and current.

As shown in FIG. 8, when moisture permeation does not occur in the display apparatus 100, the current generated in the water sensing part WSP may be about 5×10⁻¹³A at 0V and about 2×10⁻⁹A at −20V.

When moisture permeation occurs in the display apparatus 100, the current generated in the water sensing part WSP may be about 0.5×10⁻¹¹A at 0V and about 2×10⁻⁸A at −20V. Accordingly, the amount of current generated in the water sensing part WSP may increase as moisture permeation occurs.

When strong moisture permeation occurs in the display apparatus 100, the current generated in the water sensing part WSP may be about 2×10⁻⁷A at 0V and about 3×10⁻²A at −20V. Accordingly, the amount of current generated in the water sensing part WSP may further increase as the intensity of moisture permeation, that is, the amount of moisture permeation increases.

As such, in the present disclosure, since the amount of current generated in the water sensing part WSP varies depending on the degree of moisture penetration, that is, the intensity of moisture permeation, by detecting the current, the intensity of moisture permeation can be accurately detected.

Referring to FIG. 6 again, the second encapsulation layer 184 may be formed inside the first dam DAM1, while the first encapsulation layer 182 and the third encapsulation layer 186 may extend to the end side of the substrate 140 across the first dam DAM1 and the second dam DAM2. Accordingly, the first encapsulation layer 182 and the third encapsulation layer 186 may exist over the water sensing part WSP.

As described above, in the present disclosure, the water sensing part WSP may be provided under the second dam DAM2 in the non-display area NA to measure the location and amount of moisture permeation when moisture permeates, so that the defects in the display apparatus 100 due to the moisture permeation can be quickly and easily determined. In addition, even when moisture permeation occur, only the display apparatus 100 in which moisture permeates to a degree that actually affects the display apparatus 100 may be judged as defective, and the display apparatus 100 in which a small amount of moisture permeates may be judged as normal, so that the number of display apparatus 100 being discarded due to defects can be reduced or minimized.

Meanwhile, in the figure, the water sensing part WSP may be formed to overlap the second dam DAM2, but the water sensing part WSP may be formed at various locations.

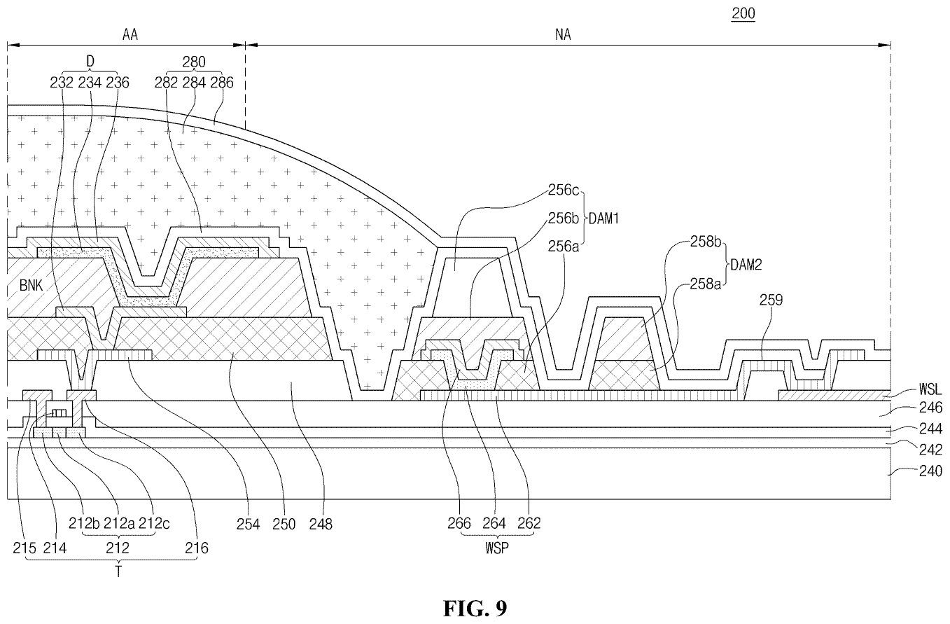

FIG. 9 is a cross-sectional view showing a display apparatus 200 according to a second embodiment of the present disclosure. Here, explanation for the same parts as those of the first embodiment of FIG. 4-6 will be omitted or shortened, and different structures from the first embodiment will be described in detail.

As shown in FIG. 9, the thin film transistor T and the light emitting diode D may be disposed in the display area AA on the substrate 240.

The thin film transistor T may include the semiconductor layer 212 disposed on the buffer layer 242, the gate electrode 214 disposed on the gate insulation layer 244, and the source electrode 215 and the drain electrode 216 disposed on the interlayer insulation layer 246.

The light emitting diode D may include the first electrode 232, the light emitting layer 234, and the second electrode 236.

The encapsulation layer 280 may be formed on the light emitting diode D in the display area AA to seal the light emitting diode D. In this case, the encapsulation layer 280 may include the first encapsulation layer 282 of an inorganic material, the second encapsulation layer 284 of an organic material, and the third encapsulation layer 286 of an inorganic material.

In the non-display area NA, the plurality of dams DAM1 and DAM2 may be provided to prevent the second encapsulation layer 284 having fluidity from passing through the perimeter of the non-display area NA and flowing out of the substrate 240. In this case, the second encapsulation layer 284 may be formed only inside the first dam DAM1, and the first encapsulation layer 282 and the third encapsulation layer 286 may extend to the end side of the substrate 240 across the first dam DAM1 and the second dam DAM2.

The first dam DAM1 may include the first layer 256a, the second layer 256b, and the third layer 256c. In this case, the first layer 256a may be disposed on the interlayer insulation layer 246, and may be formed of the same material as the second planarization layer 250. The second layer 256b may be disposed on the first layer 256a, and may be formed of the same material as the bank layer BNK. The third layer 256c may be disposed on the second layer 256b and may be formed of an organic material. The third 256c may be a spacer on which a metal mask for depositing a light emitting material is placed and supported when the light emitting layer 234 is formed. However, embodiments of the present disclosure are not limited thereto.

The second dam DAM2 may include the fourth layer 258a and the fifth layer 258b. The fourth layer 258a may be disposed on the interlayer insulation layer 246, and may be formed of the same material as the second planarization layer 250. The fifth layer 258b may be disposed on the fourth layer 258a, and may be formed of the same material as the bank layer BNK. However, embodiments of the present disclosure are not limited thereto.

The water sensing part WSP may be disposed in an area where the first dam DAM1 is provided. The water sensing part WSP may include the first electrode layer 262, the second electrode layer 266, and the intermediate layer 264 between the first electrode layer 262 and the second electrode layer 266.

The first electrode layer 262 may be disposed on the interlayer insulation layer 246 and formed of the same material and through the same process as the connection electrode 254, but embodiments of the present disclosure are not limited thereto.

The intermediate layer 264 may be disposed on the first layer 256a of the first dam DAM1 and electrically connected to the first electrode layer 262 through a contact hole formed in the first layer 256a. The intermediate layer 264 may be formed of metal oxide such as IGZO (indium gallium zinc oxide), IZO (indium zinc oxide), IGTO (indium gallium tin oxide), or IGO (indium gallium oxide).

The second electrode layer 266 may be disposed on the intermediate layer 264 and formed of the same material and through the same process as the first electrode 232 of the light emitting diode D, but embodiments of the present disclosure are not limited thereto.

Meanwhile, in the display apparatus 100 of the first embodiment shown in FIG. 6, the water sensing part WSP may be disposed to overlap the second dam DAM2, and in the display apparatus 200 of the second embodiment shown in FIG. 9, the water sensing part WSP may be disposed to overlap the first dam DAM1. However, embodiments of the present disclosure are not limited thereto. In other embodiments, two water sensing parts may be disposed along the perimeter of the non-display area NA to overlap the first dam DAM1 and the second dam DAM2 or not to overlap the first dam DAM1 and the second dam DAM2.

Although embodiments of the present disclosure have been described in more detail with reference to the accompanying drawings, the present disclosure is not necessarily limited to these embodiments, and various modifications may be made without departing from the technical spirit of the present disclosure. Accordingly, the embodiments disclosed in the present disclosure are not intended to limit the technical idea of the present disclosure, but are for illustrative purposes, and the scope of the technical idea of the present disclosure is not limited by these embodiments. Therefore, the embodiments described above should be understood in all respects as illustrative and not restrictive.

In the present disclosure, by providing the water sensing part in which electrical conductivity increases as moisture permeates, the location of moisture penetrating can be accurately detected, so that actions to the location of moisture permeation can be quickly and accurately taken.

Additionally, in the present disclosure, since the amount of moisture penetrating can be accurately detected, only the display apparatus in which moisture permeates to a degree that actually affects the display apparatus may be judged as defective, and the display apparatus in which a small amount of moisture permeates may be judged as normal, so that the number of display apparatus being discarded due to defects can be reduced or minimized.

As such, it is possible to reduce or minimize the number of display apparatus discarded as defective, thereby reducing hazardous substances and achieving a recycling effect.

It will be apparent to those skilled in the art that various modifications and variations can be made in the display device of the present disclosure without departing from the technical idea or scope of the disclosure. Thus, it is intended that the present disclosure cover the modifications and variations of this disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a display area including a plurality of sub-pixels and a non-display area adjacent to the display area;
a thin film transistor and a light emitting diode disposed in each sub-pixel of the display area;
an encapsulation layer on the light emitting diode; and
a sensing part disposed in the non-display area, the sensing part configured to detect moisture penetration,
wherein an amount of current in the sensing part changes according to a change in an amount of moisture penetrating.

2. The display apparatus of claim 1, further comprising:
a first planarization layer on the thin film transistor;
a connection electrode on the first planarization layer and electrically connecting a drain electrode of the thin film transistor and a first electrode of the light emitting diode;
a second planarization layer on the connection electrode and the first planarization layer; and
a bank layer on the second planarization layer, the bank layer surrounding each sub-pixel from a plan view.

3. The display apparatus of claim 2, wherein the sensing part is disposed along a boundary of the display area.

4. The display apparatus of claim 2, wherein the sensing part is disposed to correspond to an area where stress is applied to the display area.

5. The display apparatus of claim 3, wherein the sensing part is disposed in a folding area or a curved area of the substrate.

6. The display apparatus of claim 2, further comprising:
an interlayer insulation layer between the substrate and the first planarization layer;
a first dam disposed in the non-display area; and
a second dam adjacent to the first dam,
wherein the sensing part overlaps at least one of the first dam and the second dam.

7. The display apparatus of claim 6, wherein the first dam includes:
a first layer on the interlayer insulation layer;
a second layer on the first layer; and
a third layer on the second layer,
wherein the first layer is of a same material as the second planarization layer, the second layer is of a same material as the bank layer, and the third layer is a spacer.

8. The display apparatus of claim 7, wherein the sensing part includes:
a first electrode layer on the interlayer insulation layer under the first dam;
an intermediate layer on the first layer of the first dam and electrically connected to the first electrode layer through a contact hole formed in the first layer; and
a second electrode layer on the intermediate layer.

9. The display apparatus of claim 8, wherein the first electrode layer is of a same material as the connection electrode, and
wherein the second electrode layer is of a same material as the first electrode of the light emitting diode.

10. The display apparatus of claim 9, wherein the intermediate layer is formed of metal oxide whose electrical conductivity increase as it combines with hydrogen atom radicals.

11. The display apparatus of claim 10, wherein the metal oxide is a material selected from a group including IGZO (indium gallium zinc oxide), IZO (indium zinc oxide), IGTO (indium gallium tin oxide), and IGO (indium gallium oxide).

12. The display apparatus of claim 6, wherein the second dam includes:
a fourth layer on the interlayer insulation layer; and
a fifth layer on the fourth layer,
wherein the fourth layer is of a same material as the second planarization layer, and the fifth layer is of a same material as the bank layer.

13. The display apparatus of claim 12, wherein the sensing part includes:
a first electrode layer on the interlayer insulation layer under the second dam;
an intermediate layer on the fourth layer of the second dam and electrically connected to the first electrode layer through a contact hole formed in the fourth layer; and
a second electrode layer on the intermediate layer.

14. The display apparatus of claim 13, wherein the intermediate layer is formed of a material selected from a group including IGZO (indium gallium zinc oxide), IZO (indium zinc oxide), IGTO (indium gallium tin oxide), and IGO (indium gallium oxide).

15. The display apparatus of claim 1, further comprising:
a sensing line disposed in the non-display area and connected to the sensing part; and
a sensing circuit electrically connected to the sensing line and detecting moisture permeation based on currents input from the sensing part.

16. The display apparatus of claim 15, wherein the sensing circuit includes:
a current detection circuit configured to detect the current input from the sensing part through the sensing line;
a comparison circuit configured to compare the current detected by the current detection unit with a stored reference value;

17. The display apparatus of claim 16, wherein the sensing circuit further includes: a water position determination circuit configured to determine an area where moisture penetrates based on a value compared by the comparison circuit.

18. The display apparatus of claim 17, wherein the sensing circuit further includes: a water amount determination circuit configured to determine the amount of moisture that penetrates based on a value compared by the comparison circuit.
